(19) United States
(12) Patent Application Publication
(10) Pub. No.: US 2024/0098977 A1
(43) Pub. Date: Mar. 21, 2024

(54) SEMICONDUCTOR DEVICE

(71) Applicant: Kioxia Corporation, Tokyo (JP)

(72) Inventors: Takashi Inukai, Yokohama Kanagawa (JP); Hiroki Tokuhira, Kawasaki Kanagawa (JP); Tsuneo Inaba, Kamakura Kanagawa (JP)

(73) Assignee: Kioxia Corporation, Tokyo (JP)

(21) Appl. No.: 18/467,887

(22) Filed: Sep. 15, 2023

(30) Foreign Application Priority Data
Sep. 20, 2022 (JP) 2022-149230

(51) Int. Cl. H10B 12/00

(52) U.S. Cl. CPC H10B 12/33; H10B 12/482; H10B 12/488

(57) ABSTRACT

According to one embodiment, a semiconductor device includes a first wiring line provided in a first layer and extending in a first direction, a second wiring line provided in a second layer and extending in the first direction, a first semiconductor layer penetrating the first wiring line without penetrating the second wiring line and extending in a second direction, a second semiconductor layer penetrating the second wiring line without penetrating the first wiring line and extending in the second direction, a first insulating layer provided between the first wiring line and the first semiconductor layer, a second insulating layer provided between the second wiring line and the second semiconductor layer.

### CROSS-REFERENCE TO RELATED APPLICATIONS

This application is based upon and claims the benefit of priority from Japanese Patent Application No. 2022-149230, filed Sep. 20, 2022, the entire contents of which are incorporated herein by reference.

### FIELD

Embodiments described herein relate generally to a semiconductor device.

### BACKGROUND

A semiconductor device in which vertical transistors are integrated on a semiconductor substrate has been proposed. The vertical transistor is a transistor in which a semiconductor pillar extending in a direction intersecting the main surface of the semiconductor substrate is used as a channel, and a gate electrode surrounding the semiconductor pillar is formed of a wiring line extending along the surface of the substrate, for example.

### BRIEF DESCRIPTION OF THE DRAWINGS

FIG. 1 is a cross-sectional view schematically showing a basic configuration (general configuration) of a semiconductor device according to an embodiment.

FIG. 2 is a cross-sectional view schematically showing a configuration of a semiconductor device according to the first embodiment.

FIG. 3 is a cross-sectional view schematically showing a configuration of the semiconductor device according to the first embodiment.

FIG. 4 is a cross-sectional view schematically showing a configuration of a semiconductor device according to a first modified example of the first embodiment.

FIG. 5 is a cross-sectional view schematically showing a configuration of a semiconductor device according to a second modified example of the first embodiment.

FIG. 6 is a cross-sectional view schematically showing a configuration of a semiconductor device according to a second embodiment.

FIG. 7 is a cross-sectional view schematically showing a configuration of the semiconductor device according to the second embodiment.

FIG. 8 is a cross-sectional view schematically showing a configuration of a semiconductor device according to a modified example of the second embodiment.

FIG. 9 is a cross-sectional view schematically showing a configuration of a semiconductor device according to a third embodiment.

FIG. 10 is a cross-sectional view schematically showing a configuration of the semiconductor device according to the third embodiment.

FIG. 11 is a cross-sectional view schematically showing a configuration of a semiconductor device according to a first modified example of the third embodiment.

FIG. 12 is a cross-sectional view schematically showing a configuration of a semiconductor device according to a second modified example of the third embodiment.

FIGS. 13A, 13B, 13C, 13D, 13E, 13F, 13G, 13H, 13I, 13J, 13K, 13L and 13M each are a view schematically illustrating a respective part of a method of manufacturing a semiconductor device according to a fourth embodiment.

FIGS. 14A, 14B, 14C, 14D, 14E and 14F each are a view schematically illustrating a respective part of a method of manufacturing the semiconductor device according to the fourth embodiment when it is partly changed.

FIG. 15 is a cross-sectional view schematically showing a configuration of the semiconductor device according to the fourth embodiment.

FIG. 16 is a cross-sectional view schematically showing a configuration of a semiconductor device according to a modified example of the fourth embodiment.

### DETAILED DESCRIPTION

In general, according to one embodiment, a semiconductor device includes: a first wiring line provided in a first layer and extending in a first direction; a second wiring line provided in a second layer located on an upper layer side of the first layer and extending in the first direction; a first semiconductor layer penetrating the first wiring line without penetrating the second wiring line and extending in a second direction intersecting the first direction; a second semiconductor layer penetrating the second wiring line without penetrating the first wiring line and extending in the second direction; a first insulating layer provided between the first wiring line and the first semiconductor layer; a second insulating layer provided between the second wiring line and the second semiconductor layer; a first capacitor electrically connected to a first end portion of the first semiconductor layer; and a second capacitor electrically connected to a first end portion of the second semiconductor layer.

Embodiments will be described hereinafter with reference to the accompanying drawings.

(Basic Configuration)

First, the basic configuration (general configuration) of a semiconductor device of the embodiment will be described.

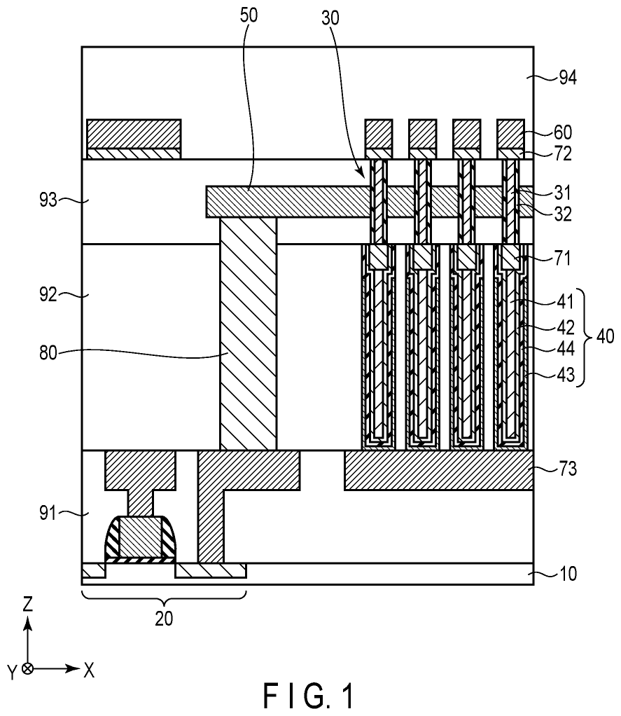

FIG. 1 is a cross-sectional view schematically showing a basic configuration (general configuration) of the semiconductor device according to the embodiment. The semiconductor device shown in FIG. 1 functions as a dynamic random access memory (DRAM). Note that an X direction, Y direction and Z direction shown in FIG. 1 intersect with each other. Specifically, the X direction, Y direction and Z direction are orthogonal to each other. This is also the case for the other drawings.

The semiconductor device of FIG. 1 comprises a semiconductor substrate 10, peripheral circuit transistors 20, vertical transistors 30, capacitors 40, word lines 50, bit lines 60, electrodes 71, 72 and 73, a plug 80 and interlayer insulating layers 91, 92, 93 and 94.

The vertical transistors 30 and the capacitors 40 connected to the vertical transistors 30 constitute memory cells of the DRAM.

The vertical transistors 30 each include a semiconductor layer 31 and a gate insulating layer 32, and a channel is formed in the semiconductor layer 31. The semiconductor layer 31 extends in the Z direction, and the electrode 71 is connected to one end of the semiconductor layer 31 and the electrode 72 is connected to the other end of the semiconductor layer 31. The semiconductor layer 31 is formed of an oxide semiconductor.

The capacitors 40 each include conductive layers 41 to 43, and a capacitor insulating layer 44, and the conductive layer 41 is connected to the electrode 71 and the conductive layer 43 is connected to the electrode 73.

The word lines 50 each extend in the X direction and serves as a gate electrode of the vertical transistor 30. Specifically, the word line 50 surrounds the semiconductor layer 31, and the semiconductor layer 31 penetrates the word line 50. A gate insulating layer 32 is provided between the word line 50 and the semiconductor layer 31. Although only one word line 50 is shown in FIG. 1, in reality, a plurality of word lines 50 are arranged along the Y direction, and each word line 50 extends in the X direction.

The bit lines 60 are each connected to the semiconductor layer 31 of the respective vertical transistor 30 via the respective electrode 72. The plurality of bit lines 60 are arranged along the X direction and each bit line 60 extend in the Y direction.

As can be seen from the above-provided descriptions, a plurality of word lines 50, each extending in the X direction, are arranged along the Y direction, and a plurality of bit lines 60, each extending in the Y direction, are arranged along the X direction. A plurality of memory cells are provided at respective intersections of the plurality of word lines 50 and the plurality of bit lines 60, and each memory cell is constituted by the vertical transistor 30 and the capacitor 40.

Note that in the example shown in FIG. 1, the capacitor 40 is electrically connected to a bottom electrode (electrode 71) of the vertical transistor 30 and the bit line 60 is electrically connected to a top electrode (electrode 72) of the vertical transistor 30. But, reversely, the top electrode (the electrode 72) of the vertical transistor 30 may be electrically connected to the capacitor 40, and the bottom electrode (the electrode 71) of the vertical transistor 30 may be electrically connected to the bit line 60.

The configuration in FIG. 1 shows the basic configuration (general configuration) of a DRAM that employs vertical transistors, and in the first to fourth embodiments to be provided below, the configuration shown in FIG. 1 is modified as appropriate.

### First Embodiment

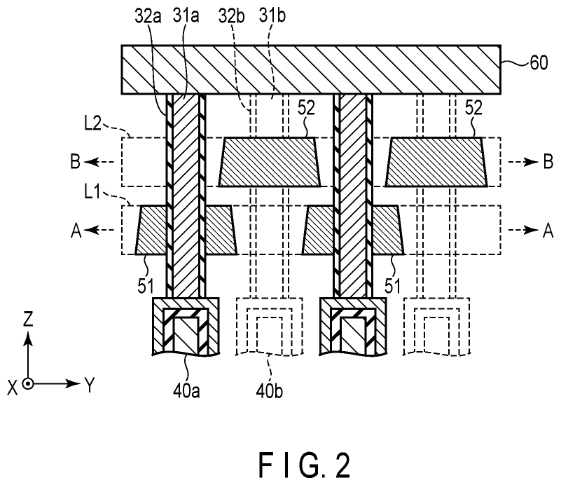

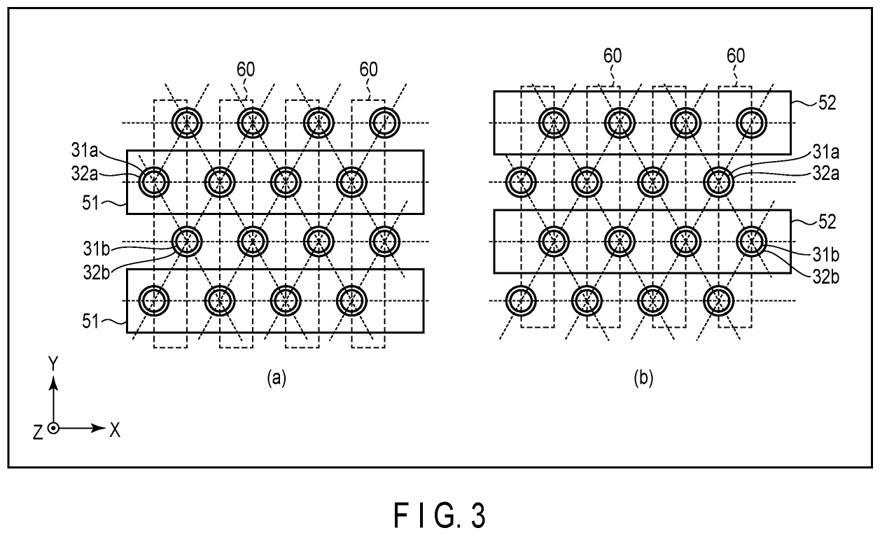

FIGS. 2 and 3 each are a cross-sectional view schematically showing a configuration of a semiconductor device of the first embodiment. FIG. 2 is a cross-sectional view parallel to the Z direction, and FIG. 3 is a cross-sectional view perpendicular to the Z direction. The cross-section taken along line A-A in FIG. 2 corresponds to FIG. 3, part (a), and the cross-section taken along line B-B in FIG. 2 corresponds to FIG. 3, part (b).

As shown in FIGS. 2 and 3, this embodiment includes a plurality of word lines 51 provided in a first layer L1 and a plurality of word lines 52 provided in a second layer L2 located on an upper layer side of the first layer L1. The word lines 51 and the word lines 52 each extend in the X direction. The word lines 51 and the word lines 52 are spaced apart from each other and are arranged alternately along the Y direction. Further, in a region between adjacent word lines 51, a region between adjacent word lines 52 and a region between the word line 51 and the word line 52, interlayer insulating films (not shown) are provided, respectively.

Semiconductor layers 31a each penetrate the respective word line 51 without penetrating the word line 52 and extends in the Z direction. Semiconductor layers 31b each penetrate the respective word line 52 without penetrating the word line 51 and extends in the Z direction. As viewed from the Z direction, a plurality of semiconductor layers 31a penetrating the same word line 51 are arranged linearly along the X direction. Similarly, as viewed from the Z direction, a plurality of semiconductor layers 31b penetrating the same word line 52 are arranged linearly along the X direction. Further, as viewed from the Y direction, the semiconductor layers 31a and the semiconductor layers 31b are arranged to be displaced from each other in the X direction. Note that in the following descriptions, the semiconductor layers 31a and the semiconductor layers 31b may be referred to simply as semiconductor layers 31.

As viewed from the Z direction, six semiconductor layers 31 that surround an arbitrary semiconductor layer 31 are located at the same distance from the arbitrary semiconductor layer 31 and are positioned at vertexes of a regular hexagon in which the arbitrary semiconductor layer 31 is placed at its center.

A gate insulating layer 32a is provided between a word line 51 and a semiconductor layer 31a, and the gate insulating layer 32a surrounds a side surface of the semiconductor layer 31a and extends along the Z direction. Similarly, a gate insulating layer 32b is provided between a word line 52 and a semiconductor layer 31b, and the gate insulating layer 32b surrounds a side surface of the semiconductor layer 31b and extends along the Z direction.

The word line (gate electrode) 51, the semiconductor layer 31a and the gate insulating layer 32a constitute a vertical transistor. Similarly, vertical transistor is formed by the word line (gate electrode) 52, the semiconductor layer 31b, and gate insulating layer 32b.

To one end (first end portion) of each semiconductor layer 31a, a capacitor 40a is electrically connected. Similarly, a capacitor 40b is electrically connected to one end (first end portion) of each semiconductor layer 31b.

Above the semiconductor layers 31a and the semiconductor layers 31b, a plurality of bit lines 60 are provided, each of which extends along the Y direction. Each bit line 60 is electrically connected to the other end (second end portion) of the semiconductor layer 31a and electrically connected to the other end (second end portion) of the semiconductor layer 31b. In other words, each bit line 60 is electrically connected commonly to adjacent semiconductor layer 31a and semiconductor layer 31b.

As described above, in this embodiment, the word lines 51 are provided in the first layer L1, and the word lines 52 are provided in the second layer L2. With such a configuration, it is possible to obtain an excellent semiconductor device (DRAM including vertical transistors) as described below.

If a plurality of word lines are provided in the same layer, the following problems may arise. As described above, the semiconductor layer of each vertical transistor penetrates the respective word line. In other words, the word line surrounds the semiconductor layer. With this configuration, when the pitch of the word lines is reduced, the line width of the word line becomes smaller in the region surrounding the semiconductor layer. As a result, there may arise the problem that the resistance of the word line becomes high due to the fine line effect. Further, when the pitch of the word lines is reduced, the distance between adjacent word lines becomes smaller. As a result, the parasitic capacitance between adjacent word lines may increase and further, the withstand voltage may decrease, undesirably.

In this embodiment, the word lines 51 are provided in the first layer L1 and the word lines 52 are provided in the second layer L2. With this configuration, when the distance between the first layer L1 and the second layer L2 is increased to some extent, the distance between the word line 51 and the word line 52 can be increased. Further, the line width of each of the word line 51 and the word line 52 can be increased. Therefore, in this embodiment, the above-discussed problems can be avoided, thereby making it possible to obtain an excellent semiconductor device.

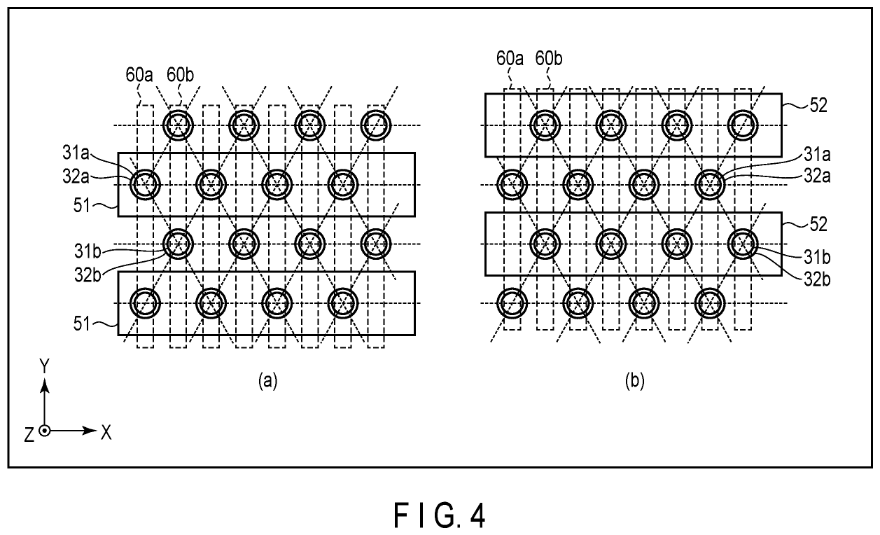

FIG. 4 is a cross-sectional view perpendicular to the Z direction, schematically showing the configuration of the semiconductor device according to a first modified example of this embodiment. The cross-sectional view parallel to the Z direction is similar to that of FIG. 2, and the cross-section taken along line A-A in FIG. 2 corresponds to FIG. 4, part (a) and the cross-section taken along line B-B in FIG. 2 corresponds to FIG. 4, part (b).

In this modified example, the configuration of the bit lines is different from that of the embodiment described above. In this modified example, the bit line 60a is electrically connected to the second end portion of the semiconductor layer 31a, and the bit line 60b is electrically connected to the second end portion of the semiconductor layer 31b. On the other hand, the bit line 60a is not connected to the second end portion of the semiconductor layer 31b and the bit line 60b is not connected to the second end portion of the semiconductor layer 31a. That is, in this modified example, unlike the embodiment described above, the bit line 60a is not electrically connected commonly to the semiconductor layer 31a and the semiconductor layer 31b, and the bit line 60b is not electrically connected commonly to the semiconductor layer 31a and the semiconductor layer 31b. Here, the vertical transistor including the semiconductor layer 31a and the vertical transistor including the semiconductor layer 32a are controlled by different word lines, and therefore the bit line 60a and the bit line 60b are not activated at the same time. With this configuration, when one of the bit line 60a and the bit line 60b is in activation, the other bit line can be used as a reference signal line.

In this modified example, the basic configuration is similar to that of the embodiment described above, and effects similar to those of the embodiment described above can be obtained.

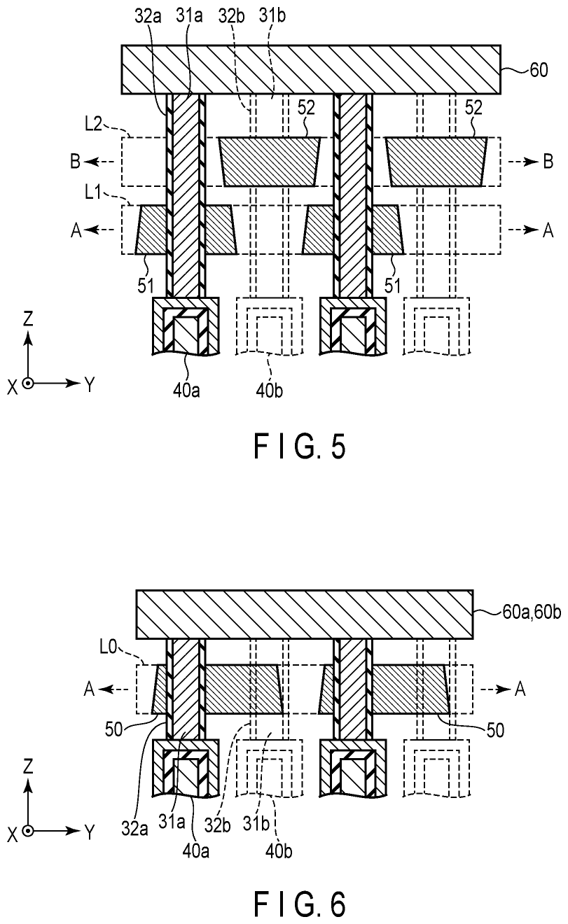

FIG. 5 is a cross-sectional view parallel to the Z direction, schematically showing the configuration of the semiconductor device according to a second modified example of the embodiment. The cross-sectional view perpendicular to the Z direction is similar to that of FIG. 3 or 4.

In this modified example, as viewed from the X direction, an upper corner of the word line 51 has an obtuse angle and a lower corner of the word line 52 has an obtuse angle. That is, in this modified example, the corners of the word line 51 and the word line 52, which mutually oppose each other, are obtuse angles. The word line 52 is formed by a method different from that of the word line 51, and it is also possible to use a material different from that of the word line 51 according to the formation method.

In this modified example, the basic configuration is similar to that of the above-described embodiment, and effects similar to those of the above-described embodiment can be obtained. Further, in this modified example, the upper corner of the word line 51 and the lower corner of the word line 52 are both set to obtuse angles, and with this configuration, it is possible to reduce the electric field between the word line 51 and the word line 52 and to reduce the capacitance between the word line 51 and the word line 52.

### Second Embodiment

Next, the second embodiment will be described. The basic items thereof are similar to those of the first embodiment, and the explanation of the items described in the first embodiment will be omitted.

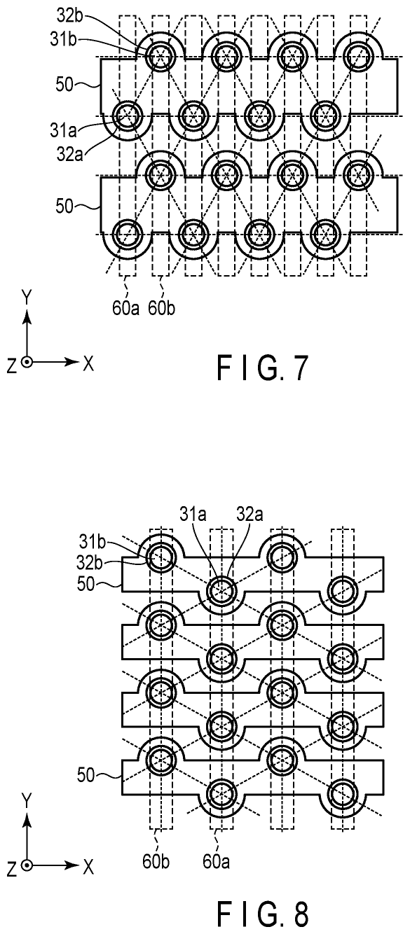

FIGS. 6 and 7 each are a cross-sectional view schematically showing a configuration of a semiconductor device of the second embodiment. FIG. 6 is a cross-sectional view parallel to the Z direction, and FIG. 7 is a cross-sectional view perpendicular to the Z direction. The cross-section taken along line A-A in FIG. 6 corresponds to FIG. 7.

As shown in FIGS. 6 and 7, in this embodiment, a plurality of word lines 50, each extending in the X direction, are provided in the same layer L0.

The semiconductor layers 31a and the semiconductor layers 31b penetrate the word line 50 and extend in the Z direction. As viewed from the X direction, the semiconductor layers 31a and the semiconductor layers 31b are disposed to be displaced from each other in the Y direction. The plurality of semiconductor layers 31a are arranged linearly in the X direction, and the plurality of semiconductor layers 31b are arranged linearly in the X direction. Further, as viewed from the Y direction, the semiconductor layers 31a and the semiconductor layers 31b are arranged to be displaced from each other in the X direction. In the following descriptions, the semiconductor layers 31a and the semiconductor layers 31b may be referred to simply as semiconductor layers 31.

As viewed from the Z direction, six semiconductor layers 31 that surround an arbitrary semiconductor layer 31 are disposed at the equal distance from the arbitrary semiconductor layer 31 and are positioned at the vertexes of a regular hexagon in which the arbitrary semiconductor layer 31 is at the center thereof.

Further, in this embodiment, at the location where the semiconductor layer 31 penetrates the word line 50, the word line 50 includes a shape corresponding to the arrangement of the semiconductor layers 31.

A gate insulating layer 32a is provided between the word line 50 and the semiconductor layer 31a, and the gate insulating layer 32a surrounds a side surface of the semiconductor layer 31a and extends in the Z direction. Similarly, a gate insulating layer 32b is provided between the word line 50 and the semiconductor layer 31b, and the gate insulating layer 32b surrounds a side surface of the semiconductor layer 31b and extends in the Z direction.

The word line (gate electrode) 50, the semiconductor layer 31a and the gate insulating layer 32a form a vertical transistor. Similarly, the word line (gate electrode) 50, the semiconductor layer 31b and the gate insulating layer 32b form a vertical transistor.

To one end (first end portion) of each semiconductor layer 31a is electrically connected to a capacitor 40a. Similarly, a capacitor 40b is electrically connected to one end (first end portion) of each semiconductor layer 31b.

Above the semiconductor layer 31a, a plurality of bit lines 60a are provided, each of which extends in the Y direction. Similarly, above the semiconductor layer 31b, a plurality of bit lines 60b are provided, each extending in the Y direction. The bit line 60a is electrically connected to the other end (second end portion) of the semiconductor layer 31a, and the bit line 60b is electrically connected to the other end (second end portion) of the semiconductor layer 31b. On the other hand, the bit line 60a is not connected to the second end portion of the semiconductor layer 31b, and the bit line 60b is not connected to the second end portion of the semiconductor layer 31a. That is, the bit line 60a is not electrically connected commonly to the semiconductor layer 31a and the semiconductor layer 31b, and the bit line 60b is not electrically connected commonly to the semiconductor layer 31a and the semiconductor layer 31b. In the following descriptions, the bit lines 60a and the bit lines 60b may be referred to simply as bit lines 60.

As can be seen from FIG. 7 and the above-provided descriptions, when the pitch of the word lines 50 is represented by Pw and the pitch of the bit lines 60 is represented by Pb, an equation: Pw/Pb=2×3^{1/2} can be established. That is, the pitch Pw of the word lines 50 is larger than the pitch Pb of the bit lines 60.

As described above, in this embodiment, the semiconductor layers 31a and the semiconductor layers 31b penetrate the same word line 50, and as viewed from the X direction, the semiconductor layers 31a and the semiconductor layers 31b are disposed to be displaced from each other in the Y direction. With this configuration, the pitch of the word lines 50 and the line width of the word line 50 can be increased. In this manner, it is possible to suppress problems such as the generation of the fine line effect and the increase of the electric field intensity between the word lines. Therefore, in this embodiment, an excellent semiconductor device (DRAM including vertical transistors) can be obtained.

FIG. 8 is a cross-sectional view perpendicular to the Z direction, schematically showing a configuration of a semiconductor device according to a modified example of this embodiment. The basic configuration of the cross-sectional view parallel to the Z direction is similar to that of FIG. 6, and the cross-sectional view taken along line A-A in FIG. 6 corresponds to FIG. 8.

In this modified example, the pitch of the bit lines 60 is different from that of the embodiment described above. As can be seen from comparison of FIG. 8 with FIG. 7, the pitch of the semiconductor layers 31 along the X direction in this modified example (FIG. 8) is larger than the pitch of the semiconductor layer 31 along the X direction in the embodiment described above (FIG. 7). Therefore, in this modified example, when the pitch of the word lines 50 is represented by Pw and the pitch of the bit lines 60 is represented by Pb, an equation: Pw/Pb=⅔^{1/2} can be established. That is, in this modified example as well, the pitch Pw of the word lines 50 is larger than the pitch Pb of the bit lines 60.

In this modified example, the basic configuration is similar to that of the above-described embodiment, and effects similar to those of the above-described embodiment can be obtained.

### Third Embodiment

Next, the third embodiment will be described. The basic items thereof are similar to those of the first embodiment, and the explanation of the items described in the first embodiment will be omitted.

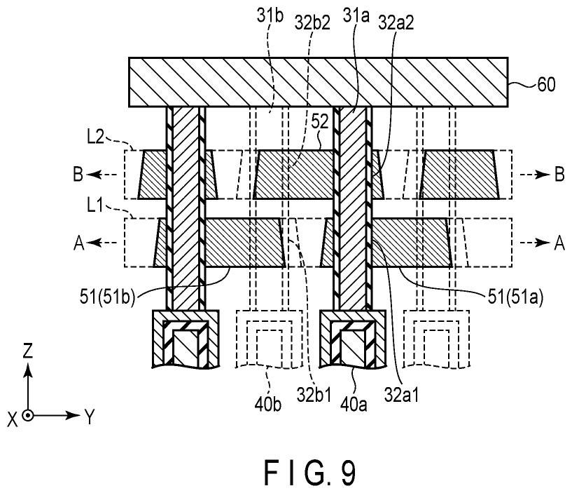

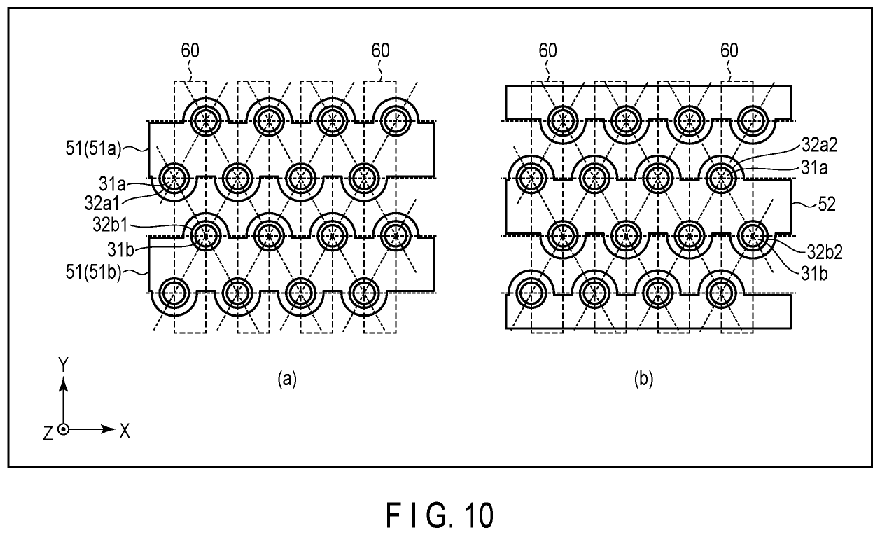

FIGS. 9 and 10 are cross-sectional views each schematically showing a configuration of a semiconductor device according to the third embodiment. FIG. 9 is a cross-sectional view parallel to the Z direction, and FIG. 10 is a cross-sectional view perpendicular to the Z direction. The cross-section taken along line A-A in FIG. 9 corresponds to FIG. 10, part (a), and the cross-section taken along line B-B in FIG. 9 corresponds to FIG. 10, part (b).

As shown in FIGS. 9 and 10, this embodiment includes a plurality of word lines 51 (51a, 51b) provided in the first layer L1 and a plurality of word lines 52 provided in the second layer L2 located on the upper layer side of the first layer L1. The word lines 51 and the word lines 52 each extend in the X direction. The word lines 51 and the word lines 52 are disposed to be spaced apart from each other and are arranged alternately along the Y direction. The word line 51a and the word line 51b are adjacent to each other along the Y direction.

Each semiconductor layer 31a penetrates the word line 51a and the word line 52 without penetrating the word line 51b and extends in the Z direction. Each semiconductor layer 31b penetrates the word line 51b and the word line 52 without penetrating the word line 51a and extends in the Z direction. The plurality of semiconductor layers 31a penetrating the word line 51a and the word line 52 are arranged linearly along the X direction. The plurality of semiconductor layers 31b penetrating the word line 51b and the word line 52 are arranged linearly in the X direction. As viewed from the Y direction, the semiconductor layers 31a and the semiconductor layers 31b are arranged to be displaced from each other in the X direction. In the following descriptions, the semiconductor layers 31a and the semiconductor layers 31b may be referred to simply as semiconductor layers 31.

As viewed from the Z direction, six semiconductor layers 31 that surround an arbitrary semiconductor layer 31 are disposed at the equal distance from the arbitrary semiconductor layer 31 and are positioned at the vertexes of a regular hexagon in which the arbitrary semiconductor layer 31 is at the center.

Between the word line 51a and the semiconductor layer 31a, a gate insulating layer 32a1 is provided and a gate insulating layer 32a2 is provided between the word line 52 and the semiconductor layer 31a. The gate insulating layers 32a1 and 32a2 are provided continuously, surround a side surface of the semiconductor layer 31a, and extend in the Z direction. Between the word line 51b and the semiconductor layer 31b, a gate insulating layer 32b1 is provided, and a gate insulating layer 32b2 is provided between the word line 52 and the semiconductor layer 31b. The gate insulating layers 32b1 and 32b2 are provided continuously, surround a side surface of the semiconductor layer 31b, and extend in the Z direction.

A vertical transistor is formed by a word line 51a, a semiconductor layer 31a and a gate insulating layer 32a1. A vertical transistor is formed by a word line 52, a semiconductor layer 31a and a gate insulating layer 32a2. A vertical transistor is formed by a word line 51b, a semiconductor layer 31b and a gate insulating layer 32b1. A vertical transistor is formed by a word line 52, a semiconductor layer 31b and a gate insulating layer 32b2.

To one end (first end portion) of each semiconductor layer 31a, a capacitor 40a is electrically connected. Similarly, a capacitor 40b is electrically connected to one end (first end portion) of each semiconductor layer 31b.

Above the semiconductor layer 31a and semiconductor layer 31b, a plurality of bit lines 60 are provided, each of which extends in the Y direction. Each bit line 60 is electrically connected to the other end (second end portion) of the semiconductor layer 31a and electrically connected to the other end (second end portion) of the semiconductor layer 31b. That is, each bit line 60 is electrically connected commonly to adjacent semiconductor layers 31a and 31b.

As described above, in this embodiment, each semiconductor layer 31 penetrates two word lines 51 and 52. Therefore, two vertical transistors connected in series are formed for each semiconductor layer 31. That is, in this embodiment, two vertical transistors connected in series are provided in one memory cell, and a capacitor is connected to the two vertical transistors connected in series.

Therefore, in this embodiment, both of the two series-connected vertical transistors contained in a desired memory cell are set to an on state, and therefore writing or reading to or from the desired memory cell can be carried out. When the vertical transistors are N-type transistors, it is possible to write to or read from the desired memory cell by applying a high voltage to the two word lines 51 and 52 that constitute the two vertical transistors contained in the desired memory cell.

As described above, in this embodiment, the word lines 51 (51a and 51b) are provided in the first layer L1 and the word lines 52 are provided in the second layer L2. With this configuration, when the distance between the first layer L1 and the second layer L2 is set to some extent, the distance between the word line 51 and the word line 52 can be increased. Further, the line width of each of the word line 51 and the word line 52 can be increased. In this way, it is possible to suppress problems such as the occurrence of the fine line effect and the increase in the electric field intensity between the word lines. Therefore, in this embodiment, an excellent semiconductor device can be obtained.

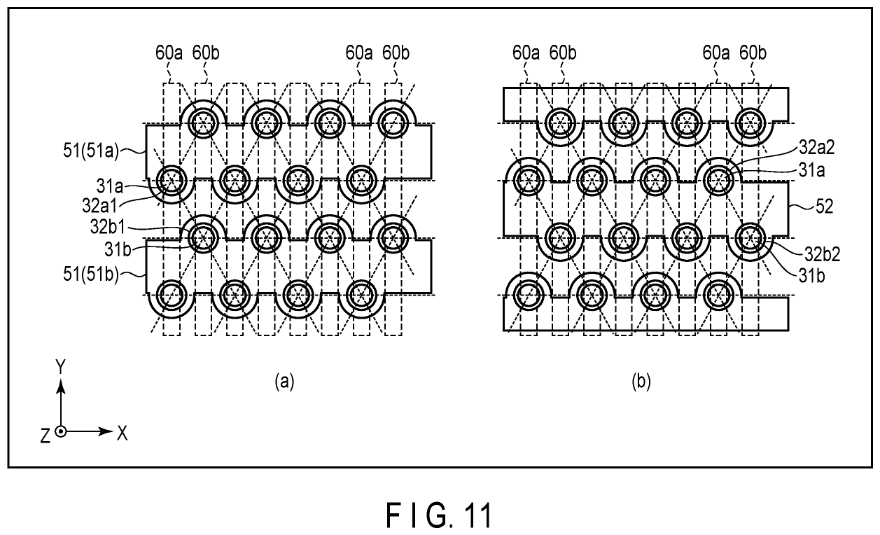

FIG. 11 is a cross-sectional view perpendicular to the Z direction, schematically showing a configuration of a semiconductor device according to a first modified example of this embodiment. The cross-sectional view parallel to the Z direction is similar to FIG. 9, and the cross-sectional view taken along line A-A in FIG. 9 corresponds to FIG. 11, part (a), and the cross-sectional view taken along line B-B in FIG. 9 corresponds to FIG. 11, part (b).

In this modified example, the configuration of the bit lines is different from that of the embodiment described above. In this modified example, the bit line 60a is electrically connected to the second end portion of the semiconductor layer 31a, and the bit line 60b is electrically connected to the second end portion of the semiconductor layer 31b. On the other hand, the bit line 60a is not connected to the second end portion of the semiconductor layer 31b and the bit line 60b is not connected to the second end portion of the semiconductor layer 31a. That is, in this modified example, unlike the embodiment described above, the bit line 60a is not electrically connected commonly to the semiconductor layer 31a and the semiconductor layer 31b, and the bit line 60b is not electrically connected commonly to the semiconductor layer 31a and the semiconductor layer 31b. Here, the bit lines 60a and 60b are not activated at the same time because the combinations of word lines driven to access the capacitors connected to the bit lines 60a and the bit lines 60b are different. Therefore, when one of the bit lines 60a and 60b is activated, the other can be used for a reference signal.

In this modified example, the basic configuration is similar to that of the above-described embodiment, and effects similar to those of the above-described embodiment can be obtained.

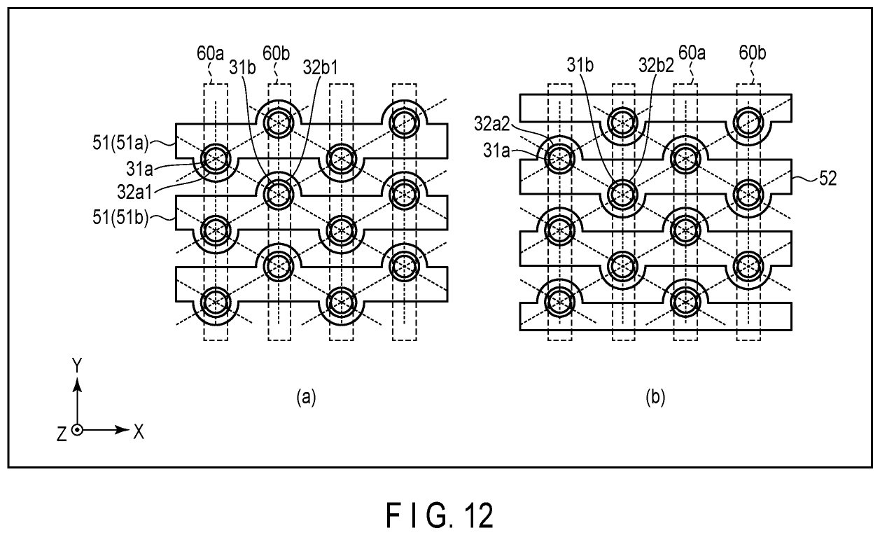

FIG. 12 is a cross-sectional view perpendicular to the Z direction, schematically showing a configuration of a semiconductor device according to a second modified example of the embodiment. The basic cross-sectional view parallel to the Z direction is similar to that of FIG. 9, and the cross-sectional view taken along line A-A in FIG. 9 corresponds to FIG. 12, part (a), and the cross-section view taken along line B-B in FIG. 9 corresponds to FIG. 12, part (b).

This modified example as well is different from the embodiment described above in the configuration of the bit lines, that is, the bit line 60a is electrically connected to the second end portion of the semiconductor layer 31a and the bit line 60b is electrically connected to the second end portion of the semiconductor layer 31b. On the other hand, the bit line 60a is not connected to the second end portion of the semiconductor layer 31b and the bit line 60b is not connected to the second end portion of the semiconductor layer 31a. That is, in this modified example as well, the bit line 60a is not electrically connected commonly to the semiconductor layer 31a and the semiconductor layer 31b, and the bit line 60b is not electrically connected commonly to the semiconductor layer 31a and the semiconductor layer 31b.

Further, in this modified example, the pitch of the bit lines 60 is different from that of the first modified example. In the first modified example, when the pitch of the word lines 51 and that of the word lines 52 are represented by Pw and the pitch of the bit lines 60 is represented by Pb, an equation: Pw/Pb=2×3^{1/2}. On the other hand, in this modified example, Pw/Pb=⅔^{1/2}.

In this modified example, the basic configuration is similar to that of the above-described embodiment, and effects similar to those of the above-described embodiment can be obtained.

### Fourth Embodiment

Next, the fourth embodiment will be described. The basic items thereof are similar to those of the first embodiment, and the explanation of the items described in the first embodiment will be omitted.

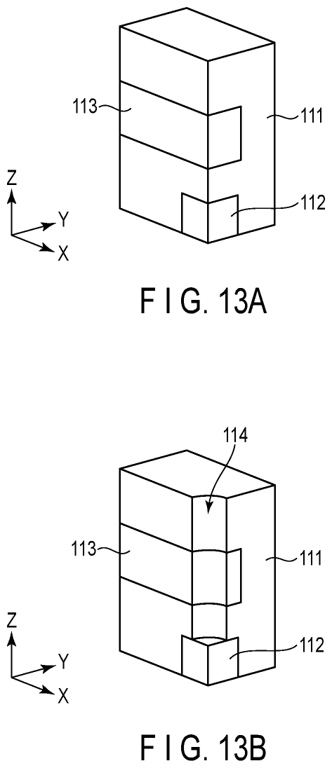

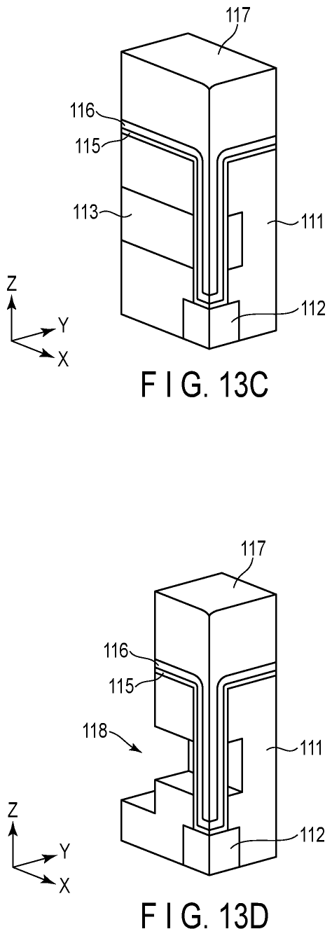

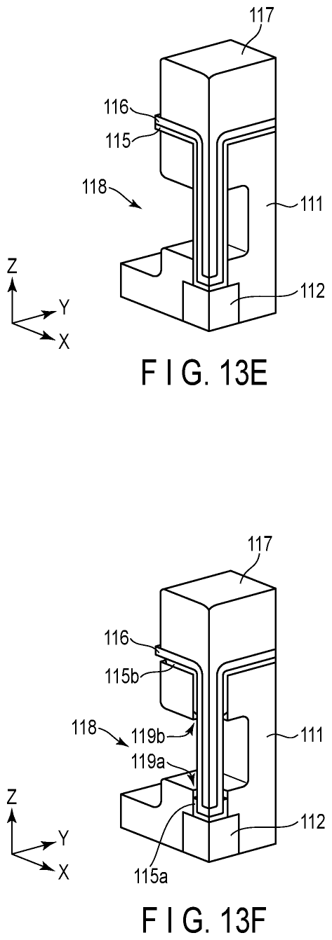

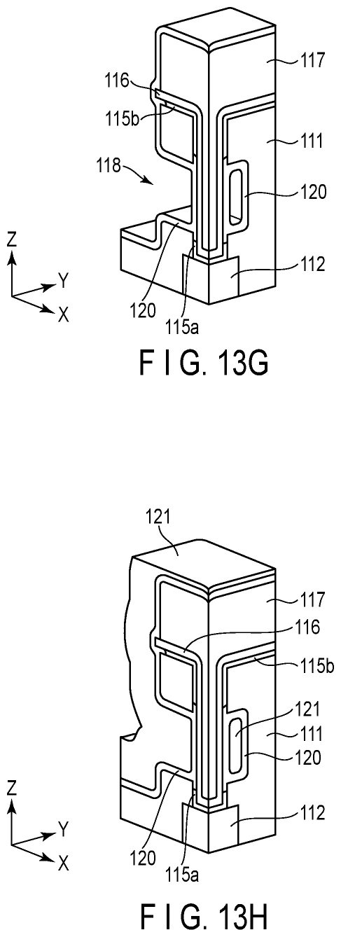

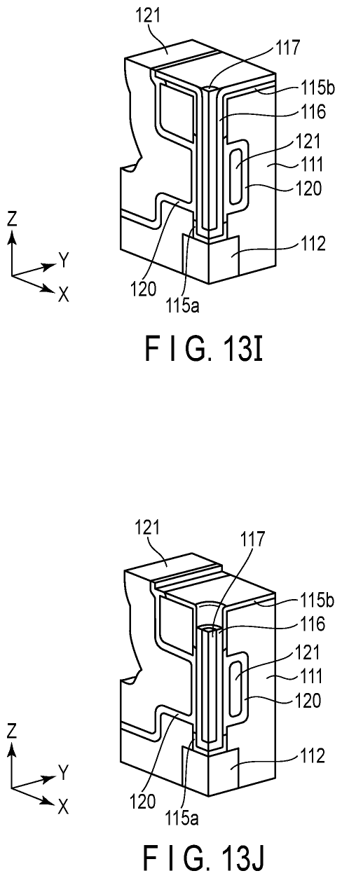

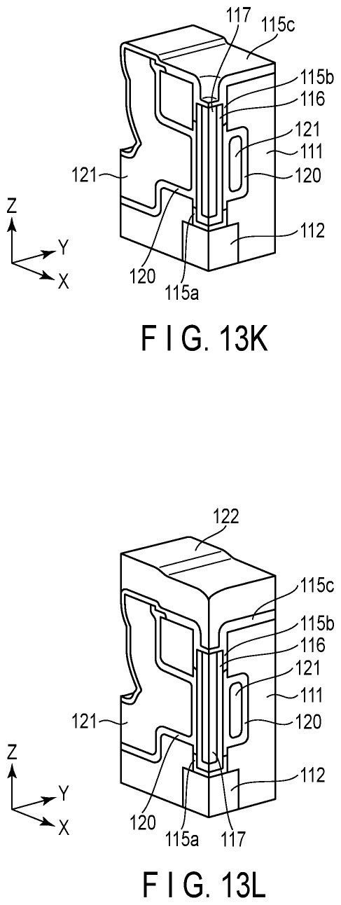

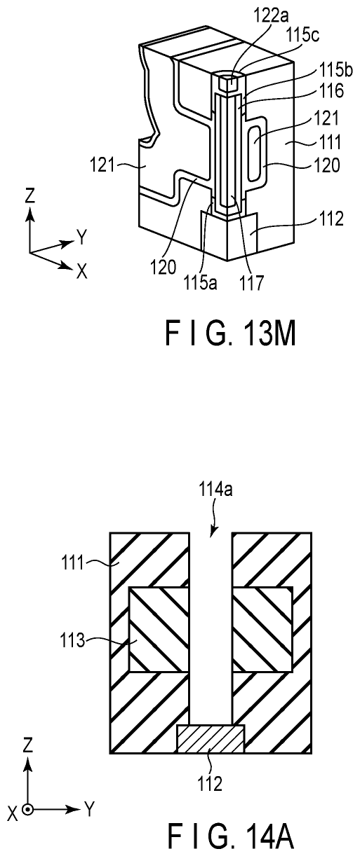

FIGS. 13A to 13M are views schematically illustrating a method of manufacturing a semiconductor device of this embodiment. More specifically, FIGS. 13A to 13M are perspective views schematically showing the structure of the semiconductor device when the device is cut along the XZ plane (plane perpendicular to the Y direction) and the YZ plane (plane perpendicular to the X direction) passing through the center line (the center line extending in the Z direction) of a semiconductor layer included in a vertical transistor.

First, the configuration shown in FIG. 13A is formed. More specifically, a configuration including an interlayer insulating layer 111, a conductive layer 112, and a sacrificial layer 113 is formed on a lower structure (not shown) including a capacitor (not shown) and the like. The conductive layer 112 is electrically connected to the capacitor.

Next, as shown in FIG. 13B, the interlayer insulating layer 111 and the sacrificial layer 113 are etched to form a hole 114 that reaches the conductive layer 112.

Then, as shown in FIG. 13C, an electrode layer 115, a semiconductor layer 116 and a core insulating layer 117 are formed in the hole 114 and on the interlayer insulating layer 111. The electrode layer 115 is formed of an oxide conductor, and the semiconductor layer 116 is formed of an oxide semiconductor such as IGZO containing indium (In), gallium (Ga), zinc (Zn) and oxygen (O).

Subsequently, as shown in FIG. 13D, the interlayer insulating layer 111 is etched to form a trench (slit) extending in the Z direction, and further the sacrificial layer 113 is removed. Thus, a cavity 118 is formed.

After that, as shown in FIG. 13E, the cavity 118 is enlarged. Note that this process may be omitted. In other words, the cavity 118 may not necessarily need to be enlarged.

Next, as shown in FIG. 13F, the exposed portion of the electrode layer 115 is etched to form a bottom electrode 115a and a top electrode 115b of the vertical transistor. In this etching process, the electrode layer 115 is over-etched to form trenches 119a and 119b.

Then, as shown in FIG. 13G, a silicon oxide layer is formed as a gate insulating layer 120 on the exposed surface of the structure obtained in the process of FIG. 13F. The gate insulating layer 120 may as well be formed inside the trenches 119a and 119b.

Subsequently, as shown in FIG. 13H, a tungsten (W) layer is formed as a gate electrode layer 121 by CVD on the surface of the gate insulating layer 120. As a result, the cavity 118 is filled with the gate electrode layer 121.

After that, as shown in FIG. 13I, the core insulating layer 117, the gate insulating layer 120 and the gate electrode layer 121 are etched to expose the semiconductor layer 116.

Next, as shown in FIG. 13J, the semiconductor layer 116 and the core insulating layer 117 are recessed to lower the position of the upper surfaces of the semiconductor layer 116 and the core insulating layer 117 below the position of the upper surface of the top electrode 115b.

Then, as shown in FIG. 13K, a cap electrode layer 115c containing an oxide conductor is formed on the structure obtained in the process of FIG. 13J. Note that this process may be omitted.

Next, as shown in FIG. 13L, a conductive layer 122 is formed on the structure obtained in the process of FIG. 13K.

After that, as shown in FIG. 13M, a planarization process is carried out on the conductive layer 122. As a result, a conductive portion 122a is formed in the recess formed in the top electrode 115b and the cap electrode layer 115c.

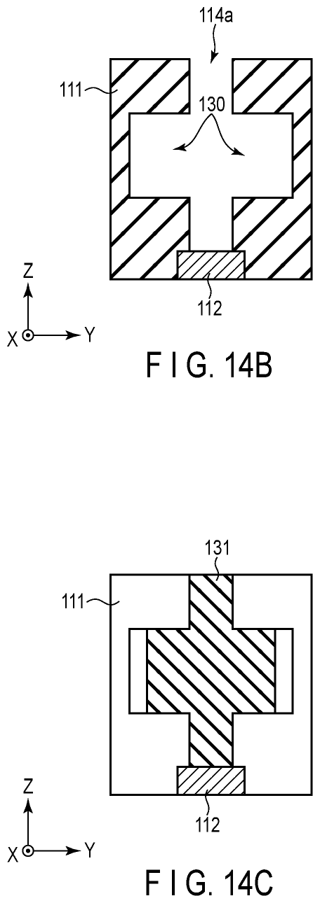

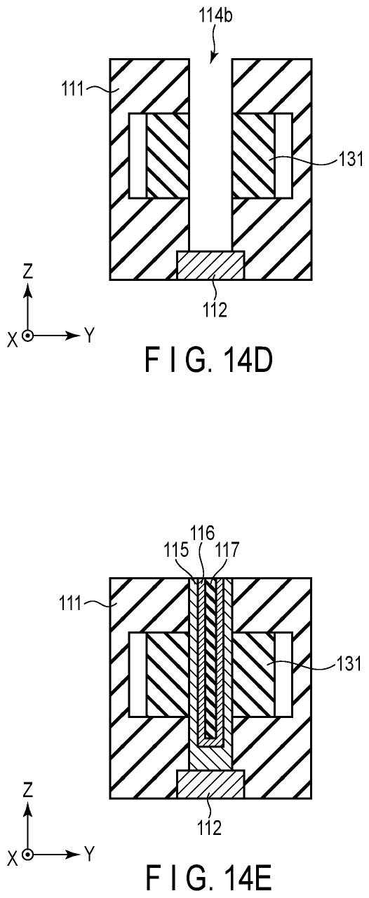

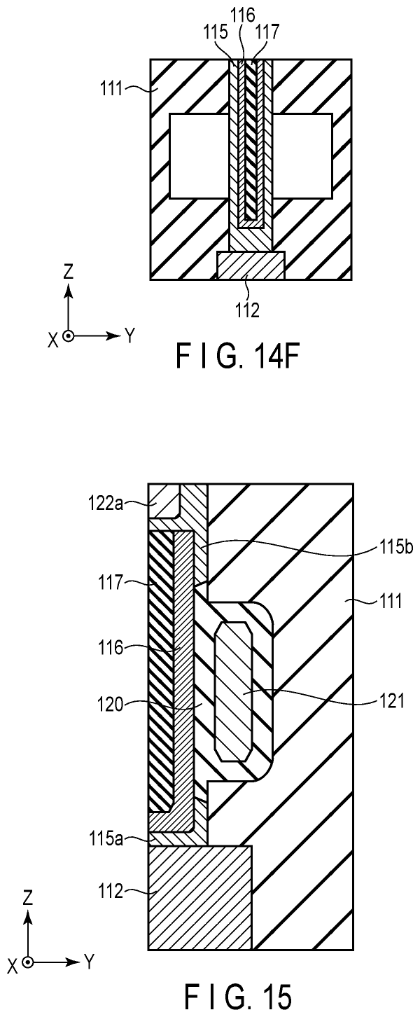

Note that in the process shown in FIG. 13D, when etching the sacrificial layer 113, the electrode layer 115 and the semiconductor layer 116 may also be etched. In such a case, a manufacturing process shown in FIG. 14A to FIG. 14F may as well be applied.

The process in FIG. 14A corresponds to the process in FIG. 13B. That is, the interlayer insulating layer 111 and the sacrificial layer 113 are etched to form a hole 114a that reaches the conductive layer 112.

Next, as shown in FIG. 14B, the sacrificial layer 113 is etched to form a cavity 130.

Then, as shown in FIG. 14C, a resist layer 131 is formed in the hole 114a and the cavity 130.

Subsequently, as shown in FIG. 14D, the resist layer 131 is etched by RIE using the interlayer insulating layer 111 as a mask to form a hole 114b.

After that, as shown in FIG. 14E, an electrode layer 115, a semiconductor layer 116 and a core insulating layer 117 are formed in the hole 114b.

Next, as shown in FIG. 14F, the resist layer 131 is removed by using an organic solvent. With use of the organic solvent, only the resist layer 131 is etched, and the electrode layer 115, the semiconductor layer 116 and the core insulating layer 117 remain unetched.

In the above-described manner, a configuration such as shown in FIG. 13D can be obtained.

FIG. 15 is a cross-sectional view schematically showing the configuration of the semiconductor device obtained by the manufacturing method shown in FIGS. 13A to 13M.

As shown in FIG. 15 and FIG. 13M, a vertical transistor including the bottom electrode 115a, the top electrode 115b, the semiconductor layer 116, the core insulating layer 117, the gate insulating layer 120 and the gate electrode 121 is formed on a lower structure (not shown) including a capacitor (not shown) and the like. The top electrode 115b may include the cap electrode layer 115c shown in the manufacturing method of FIGS. 13A to 13M. As in the basic configuration shown in FIG. 1, a capacitor (not shown) is electrically connected to the bottom electrode 115a, and a bit line (not shown) is electrically connected to the top electrode 115b.

As in the case of the basic configuration shown in FIG. 1, the gate electrode 121 functions as a word line, and the gate electrode (word line) 121 extends in the X direction. Further, as in the basic configuration shown in FIG. 1, the semiconductor layer 116 penetrates the gate electrode (word line) 121, and the gate insulating layer 120 is provided between the gate electrode (word line) 121 and the semiconductor layer 116. Furthermore, in this embodiment, the gate insulating layer 120 is formed to surround the surface (top, bottom and side surfaces) of the gate electrode (word line) 121.

Moreover, in this embodiment, the bottom electrode 115a covers the lower surface (one of the first and second end surfaces) and the outer side surface adjacent the lower surface of the semiconductor layer 116. In other words, the bottom electrode 115a is in contact with the lower surface (one of the first and second end surfaces) of the semiconductor layer 116 and the outer side surface adjacent the lower surface of the semiconductor layer 116. Similarly, the top electrode 115b covers the outer side surface adjacent the upper surface (the other of the first and second end surfaces) of the semiconductor layer 116. In the case where the cap electrode layer 115c is provided, this layer 115c covers the upper surface of the semiconductor layer 116. In other words, the cap electrode layer 115c is in contact with the upper surface (the other of the first and second end surfaces) of the semiconductor layer 116, and the top electrode 115b is in contact with the outer side surface adjacent the upper surface of the semiconductor layer 116. In this embodiment, the electrode layer 115 is formed in advance along the side surface of the semiconductor layer 116 in the process shown in FIG. 13C, such a configuration can be obtained.

In this embodiment, due to the configuration described above, the contact area between the semiconductor layer 116 and the bottom electrode 115a and the contact area between the semiconductor layer 116 and the top electrode 115b or the cap electrode layer 115c can be increased. Therefore, the contact resistance between the semiconductor layer 116 and the bottom electrode 115a and the contact resistance between the semiconductor layer 116 and the top electrode 115b or the cap electrode layer 115c can be lowered, thereby making it possible to obtain a vertical transistor with excellent characteristics.

Further, in this embodiment, the electrode layer 115 is formed along the side surface of the semiconductor layer 116 in the process shown in FIG. 13C, and therefore the bottom electrode 115a can be formed in a self-align manner with respect to the semiconductor layer 116, and the top electrode 115b can be formed in a self-align manner with respect to the semiconductor layer 116. Therefore, it is possible to reliably connect the bottom electrode 115a to the semiconductor layer 116 and the top electrode 115b to the semiconductor layer 116 each with a large connection area.

Furthermore, in this embodiment, when the gate insulating layer 120 is also formed inside the trenches 119a and 119b in the process of FIG. 13G, the gate insulating layer 120 extends along the semiconductor layer 116 in the Z direction. In the case where such a configuration is formed that the gate insulating layer 120 is in contact with the bottom electrode 115a and the top electrode 115b, the insulation properties of the element can be improved. In addition, the gate insulating layer 120 covers the semiconductor layer 116 without space, and thus the side surface of the semiconductor layer 116 can be protected.

Moreover, in this embodiment, the semiconductor layer 116 formed of an oxide semiconductor such as IGZO contains fluorine (F). That is, when a tungsten (W) layer is formed by CVD as the gate electrode layer 121 in the process shown in FIG. 13H, F is introduced into the semiconductor layer 116 because F is contained in the film formation gas. For example, the F content in the semiconductor layer 116 is about 5%. Thus, when a small amount of F is contained in the semiconductor layer 116, it is possible to suppress the threshold voltage fluctuation without decreasing the on-current of the transistor. Therefore, it is possible to obtain a vertical transistor with excellent characteristics.

It is preferable that the material of the bottom electrode 115a and the top electrode 115b contains zinc (Zn) and oxygen (O). In other words, for the bottom electrodes 115a and the top electrode 115b, a ZnO-based transparent electrode material should preferably be used. For example, AZO containing aluminum (Al), zinc (Zn) and oxygen (O), or GZO containing gallium (Ga), zinc (Zn) and oxygen (O) can be used. The ZnO-based electrode materials have an electron affinity lower than that of the IGZO used for the semiconductor layer 116, and therefore the Schottky barrier exists on the electrode side. Therefore, by using a ZnO-based electrode material for the bottom electrode 115a and the top electrode 115b, ohmic characteristics can be easily obtained.

Further, with the ZnO-based electrode material, it is possible to obtain a high etching selectivity relative to IGZO. Therefore, in the process of FIG. 13F, the electrode layer 115 can be etched at a high etching selectivity relative to the semiconductor layer (IGZO layer) 116. Note that in order to obtain a higher etching selectivity, ITZO (InₓSn_{y}Zn_{z}O_{1-x-y-z}), IGO (InₓGa_{y}O_{1-x-y}) or the like, which is chemically more stable, may be used for the semiconductor layer 116.

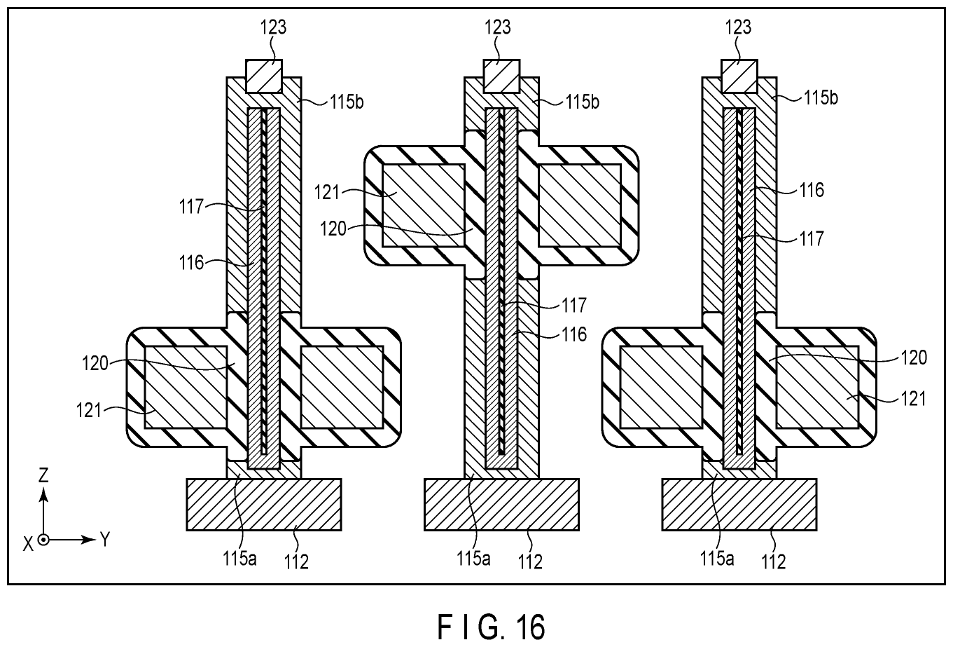

FIG. 16 is a cross-sectional view schematically showing a modified example of this embodiment.

In this modified example, as in the cases of the first and third embodiments, the gate electrode (word line) 121 has a two-layer structure. Therefore, in the vertical transistor having a configuration in which the semiconductor layer 116 penetrates the gate electrode (word line) 121 on the lower layer side, the length in the Z direction of the portion of the bottom electrode 115a that covers the outer side surface adjacent the lower surface of the semiconductor layer 116 is shorter than the length in the Z direction of the portion of the top electrode 115b that covers the outer side surface adjacent the upper surface of the semiconductor layer 116. On the other hand, in the vertical transistor having a configuration in which the semiconductor layer 116 penetrates the gate electrode (word line) 121 on the upper layer side, the length in the Z direction of the portion of the bottom electrode 115a that covers the outer side surface adjacent the lower surface of the semiconductor layer 116 is greater than the length in the Z direction of the portion of the top electrode 115b that covers the outer side surface adjacent the upper surface of the semiconductor layer 116. With this configuration, the contact resistance can be improved in both the vertical transistor having a configuration in which the semiconductor layer 116 penetrates the gate electrode 121 on the lower layer side and the vertical transistor having a configuration in which the semiconductor layer 116 penetrates the gate electrode 121 on the upper layer side.

In addition, in this modified example as well, the basic configuration is similar to that of the above-described embodiment, and effects similar to those of the above-described embodiment can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first wiring line provided in a first layer and extending in a first direction;
a second wiring line provided in a second layer located on an upper layer side of the first layer and extending in the first direction;
a first semiconductor layer penetrating the first wiring line without penetrating the second wiring line and extending in a second direction intersecting the first direction;
a second semiconductor layer penetrating the second wiring line without penetrating the first wiring line and extending in the second direction;
a first insulating layer provided between the first wiring line and the first semiconductor layer;
a second insulating layer provided between the second wiring line and the second semiconductor layer;
a first capacitor electrically connected to a first end portion of the first semiconductor layer; and
a second capacitor electrically connected to a first end portion of the second semiconductor layer.

2. The semiconductor device of claim 1, wherein
the first semiconductor layer and the second semiconductor layer are displaced from each other in the first direction as viewed from a third direction intersecting the first and second directions.

3. The semiconductor device of claim 1, further comprising:
a third wiring line electrically connected to a second end portion of the first semiconductor layer and a second end portion of the second semiconductor layer and extending in a third direction intersecting the first and second directions.

4. The semiconductor device of claim 1, further comprising:
a third wiring line electrically connected to a second end portion of the first semiconductor layer and extending in a third direction intersecting the first and second directions; and
a fourth wiring line electrically connected to a second end portion of the second semiconductor layer and extending in the third direction.

5. The semiconductor device of claim 1, wherein
the first semiconductor layer and the second semiconductor layer each contain an oxide semiconductor.

6. The semiconductor device of claim 1, wherein
as viewed from the first direction, an upper corner of the first wiring line has an obtuse angle and a lower corner of the second wiring line has an obtuse angle.

7. A semiconductor device comprising:
a first wiring line extending in a first direction;
a first semiconductor layer penetrating the first wiring line and extending in a second direction intersecting the first direction;
a second semiconductor layer penetrating the first wiring line and extending in the second direction;
a first insulating layer provided between the first wiring line and the first semiconductor layer;
a second insulating layer provided between the first wiring line and the second semiconductor layer;
a first capacitor electrically connected to a first end portion of the first semiconductor layer; and
a second capacitor electrically connected to a first end portion of the second semiconductor layer,
the first semiconductor layer and the second semiconductor layer being displaced from each other in a third direction intersecting the first and second directions, as viewed from the first direction.

8. The semiconductor device of claim 7, wherein
the first semiconductor layer and the second semiconductor layer are displaced from each other in the first direction as viewed from the third direction.

9. The semiconductor device of claim 7, further comprising:
a second wiring line electrically connected to a second end portion of the first semiconductor layer and extending in the third direction; and
a third wiring line electrically connected to a second end portion of the second semiconductor layer and extending in the third direction.

10. The semiconductor device of claim 7, wherein
the first semiconductor layer and the second semiconductor layer each contain an oxide semiconductor.

11. A semiconductor device comprising:
a first wiring line provided in a first layer and extending in a first direction;
a second wiring line provided in the first layer and extending in the first direction;
a third wiring line provided in a second layer located on an upper layer side of the first layer and extending in the first direction;
a first semiconductor layer penetrating the first wiring line and the third wiring line without penetrating the second wiring line and extending in a second direction intersecting the first direction;
a second semiconductor layer penetrating the second wiring line and the third wiring line without penetrating the first wiring line and extending in the second direction;
a first insulating layer provided between the first wiring line and the first semiconductor layer;
a second insulating layer provided between the third wiring line and the first semiconductor layer;
a third insulating layer provided between the second wiring line and the second semiconductor layer;
a fourth insulating layer provided between the third wiring line and the second semiconductor layer;
a first capacitor electrically connected to a first end portion of the first semiconductor layer; and
a second capacitor electrically connected to a first end portion of the second semiconductor layer.

12. The semiconductor device of claim 11, wherein
the first semiconductor layer and the second semiconductor layer are displaced from each other in the first direction as viewed from a third direction intersecting the first and second directions.

13. The semiconductor device of claim 11, further comprising:
a fourth wiring line electrically connected to a second end portion of the first semiconductor layer and a second end portion of the second semiconductor layer and extending in a third direction intersecting the first and second directions.

14. The semiconductor device of claim 11, further comprising:
a fourth wiring line electrically connected to a second end portion of the first semiconductor layer and extending in a third direction intersecting the first and second directions; and
a fifth wiring line electrically connected to a second end portion of the second semiconductor layer and extending in the third direction.

15. The semiconductor device of claim 11, wherein
the first semiconductor layer and the second semiconductor layer each contain an oxide semiconductor.

16. A semiconductor device comprising:
a first wiring line extending in a first direction;
a semiconductor layer penetrating the first wiring line and extending in a second direction intersecting the first direction;
an insulating layer provided between the first wiring line and the semiconductor layer;
a first electrode covering a first end surface of the semiconductor layer and a side surface adjacent to the first end surface of the semiconductor layer; and
a second electrode covering a second end surface of the semiconductor layer and a side surface adjacent to the second end surface of the semiconductor layer.

17. The semiconductor device of claim 16, further comprising:
a capacitor electrically connected to the first electrode.

18. The semiconductor device of claim 17, further comprising:
a second wiring line electrically connected to the second electrode.

19. The semiconductor device of claim 16, wherein
the semiconductor layer contains an oxide semiconductor.

20. The semiconductor device of claim 19, wherein
the semiconductor layer contains fluorine (F).

21. The semiconductor device of claim 16, wherein
the first electrode and the second electrode each contain zinc (Zn) and oxygen (O).
